(19) United States
(12) Patent Application Publication
(10) Pub. No.: US 2023/0361750 A1
(43) Pub. Date: Nov. 9, 2023

(54) ACOUSTIC WAVE DEVICE

(71) Applicant: Murata Manufacturing Co., Ltd., Nagaokakyo-shi (JP)

(72) Inventors: Tetsuya KIMURA, San Mateo, CA (US); Filip Iliev, San Francisco, CA (US); Bryant Garcia, Austin, TX (US)

(21) Appl. No.: 18/355,739

(22) Filed: Jul. 20, 2023

Related U.S. Application Data
(63) Continuation of application No. PCT/US2022/014229, filed on Jan. 28, 2022.
(60) Provisional application No. 63/143,123, filed on Jan. 29, 2021.

(51) Int. Cl. H03H 9/02; H03H 9/05

(52) U.S. Cl. CPC H03H 9/02228; H03H 9/02015; H03H 9/0504

(57) ABSTRACT

An acoustic wave device is provided that includes a support substrate, a piezoelectric layer on the support substrate, and an interdigital transducer electrode. A ratio d/p is less than or equal to approximately 0.5, where d is a thickness of the piezoelectric layer and p is a distance between centers of adjacent electrode fingers of the multiple electrode fingers. The interdigital transducer electrode includes an intersection region in which the adjacent electrode fingers overlap when viewed in a direction in which multiple electrode fingers face each other. Moreover, two gap regions are located between the intersection region and a corresponding one of the two busbars and includes an I-B gap that is a dimension in a direction in which the multiple electrode fingers extend. The I-B gap of at least one of the two gap regions is less than or equal to about 1.1p.

### CROSS REFERENCE TO RELATED APPLICATIONS

This application is a continuation of PCT/US2022/014229, filed Jan. 28, 2022, which claims priority to U.S. Provisional Application No. 63/143,123 filed on Jan. 29, 2021, the entire contents of each application of which are hereby incorporated by reference.

### TECHNICAL FIELD

The present invention relates to acoustic wave devices each including a piezoelectric layer of lithium niobate or lithium tantalate.

### BACKGROUND

Acoustic wave devices include an interdigital transducer (IDT) electrode with two busbars and electrode fingers extending from each busbar. Resonant characteristics of acoustic wave devices can be degraded if the distance between one of the busbars and the electrode fingers of the other busbar is too large.

### SUMMARY OF THE INVENTION

Accordingly, in exemplary embodiments of the present invention, acoustic wave devices are provided that each include an IDT electrode including two busbars and electrode fingers extending from each busbar in which at least one of the busbars includes an IDT-Busbar (I-B) gap between the busbar and the ends of the electrode fingers of the other busbar of less than or equal to 1.1p, where p is a distance between the centers of adjacent electrode fingers. Such a configuration inhibits the resonant characteristics from being degraded.

According to an exemplary embodiment, an acoustic wave device is provided that includes a support substrate, a piezoelectric layer on the support substrate and including lithium tantalate or lithium niobate, and an interdigital transducer electrode on the piezoelectric layer and including two busbars and multiple electrode fingers. A ratio d/p is less than or equal to about 0.5, where d is a thickness of the piezoelectric layer and p is a distance between centers of adjacent electrode fingers of the multiple electrode fingers. The interdigital transducer electrode includes an intersection region in which the adjacent electrode fingers overlap when viewed in a direction in which the multiple electrode fingers face each other; two gap regions between the intersection region and a corresponding one of the two busbars to form I-B gaps in a direction in which the multiple electrode fingers extend. Moreover, the I-B gap of at least one of the two gap regions is less than or equal to about 1.1p.

In another exemplary aspect, the I-B gap of both of the two gap regions can be less than or equal to about 1.1p. Moreover, the I-B gap of at least one of the two gap regions can be greater than or equal to about 0.5 μm and less than or equal to about 1.1p. The I-B gap of at least one of the two gap regions can be less than or equal to about 0.9p. In addition, the support substrate can include an electrically insulating layer adjacent to the piezoelectric layer that can include a cavity that faces the piezoelectric layer. At least a portion of the intersection region can overlap the cavity of the electrically insulating layer in a plan view.

In another exemplary aspect, the support substrate can include a cavity that faces the piezoelectric layer, and at least a portion of the intersection region can overlap the cavity of the support substrate in a plan view. The ratio d/p can less than or equal to about 0.24. Moreover, MR≤1.75 (d/p)+0.075, where MR is a metallization ratio of an area of the multiple electrode fingers to a total area of the intersection region of the interdigital transducer electrode.

According to another exemplary embodiment, an acoustic wave device is provided that includes a support substrate including a cavity, a piezoelectric layer on the support substrate, and an interdigital transducer electrode on the piezoelectric layer at least partially overlapping the cavity of the support substrate in a plan view. The interdigital transducer electrode includes a first bus bar, first electrode fingers extending from the first bus bar, a second bus bar, second electrode fingers extending from the second bar such that the first and the second electrode fingers are interdigitated, an intersection region in which adjacent first and second electrode fingers overlap when viewed in a direction in which the first and the second electrode fingers face each other, a first gap region between the intersection region and the first busbar to form a first I-B gap in a direction in which the first and the second electrode fingers extend, and a second gap region between the intersection region and the second busbar to form a second I-B gap in the direction in which the first and the second electrode fingers extend. A ratio d/p is less than or equal to about 0.5, where d is a thickness of the piezoelectric layer and p is a distance between centers of adjacent electrode fingers of the multiple electrode fingers, and at least one of the first and the second I-B gaps is less than or equal to about 1.1p.

In another exemplary aspect, the first and the second I-B gaps can be less than or equal to about 1.1p. Moreover, at least one of the first and the second I-B gaps can be greater than or equal to about 0.5 μm and less than or equal to about 1.1p. At least one of the first and the second I-B gaps can be less than or equal to about 0.9p.

In another exemplary aspect, the support substrate can include an electrically insulating layer adjacent to the piezoelectric layer. The cavity can be included in the electrically insulating layer and can face the piezoelectric layer, and at least a portion of the intersection region can overlap the cavity in a plan view. The cavity can be included only in the electrically insulating layer. In addition, at least a portion of the intersection region can overlap the cavity of the support substrate in a plan view.

The ratio d/p can be less than or equal to about 0.24. Moreover, MR≤1.75 (d/p)+0.075, where MR is a metallization ratio of an area of the multiple electrode fingers to a total area of the intersection region of the interdigital transducer electrode. The piezoelectric layer can include lithium tantalate or lithium niobate.

The above and other elements, features, steps, characteristics and advantages of the present invention will become more apparent from the following detailed description of the preferred embodiments with reference to the attached drawings.

### BRIEF DESCRIPTION OF THE DRAWINGS

FIG. 1A is a schematic perspective view showing an acoustic wave device according to a first exemplary embodiment.

FIG. 1B is a plan view showing an electrode structure on a piezoelectric layer.

FIG. 2 is a cross-sectional view taken along the line A-A in FIG. 1A.

FIG. 3A is a schematic elevational cross-sectional view that shows a Lamb wave propagating in a piezoelectric film of an acoustic wave device.

FIG. 3B is a cross-sectional view that shows a bulk wave propagating in a piezoelectric film of an acoustic wave device.

FIG. 4 schematically shows a bulk wave when a voltage is applied across the electrodes of an acoustic wave device.

FIG. 5 is a graph showing the resonant characteristics of the acoustic wave device according to the first exemplary embodiment.

FIG. 6 is a graph showing the relationship between the ratio d/2p and the fractional bandwidth of the acoustic wave device as a resonator.

FIG. 7 is a plan view of an acoustic wave device according to a second exemplary embodiment.

FIG. 8 is a reference graph showing an example of the resonant characteristics of the acoustic wave device according to an exemplary embodiment.

FIG. 9 is a graph showing the relationship between a fractional bandwidth and the magnitude of normalized spurious for a large number of acoustic wave resonators.

FIG. 10 is a graph showing the relationship among the ratio d/2p, the metallization ratio MR, and the fractional bandwidth.

FIG. 11 is a diagram showing a map of a fractional bandwidth of the Euler angles (0°, θ, ψ) of LiNbO₃ when the ratio d/p is brought close to zero without limit.

FIG. 12 is a cross-sectional view of an acoustic wave device including an acoustic multilayer film.

FIG. 13 is a plan view of an acoustic wave device with an interdigital transducer electrode.

FIG. 14 is a graph showing the relationship between the impedance ratio and the normalized gap between the busbar and the tips of the electrode fingers of the IDT electrode.

FIG. 15 is a graph showing the relationship between the fluctuation ratio and the normalized gap between the busbar and the tips of the electrode fingers of the IDT.

FIG. 16 shows a possible plot of impedances Z1, Z2, and Z3 used to calculate the fluctuation ratio.

FIG. 17 is a graph showing the relationship between the maximum temperature of an acoustic wave device and the normalized gap between the busbar and the tips of the electrode fingers of the IDT.

### DETAILED DESCRIPTION

Exemplary embodiments of the present invention generally include a piezoelectric layer 2 made of lithium niobate or lithium tantalate, and first and second electrodes 3, 4 opposed in a direction that intersects with a thickness direction of the piezoelectric layer 2.

In operation, a bulk wave in a first thickness-shear mode is used (e.g., excited). In addition, the first and the second electrodes 3, 4 can be adjacent electrodes, and, when a thickness of the piezoelectric layer 2 is d and a distance between a center of the first electrode 3 and a center of the second electrode 4 is p, a ratio d/p can be less than or equal to about 0.5, for example. With this configuration, the size of the acoustic wave device can be reduced, and the Q value or quality factor can be increased.

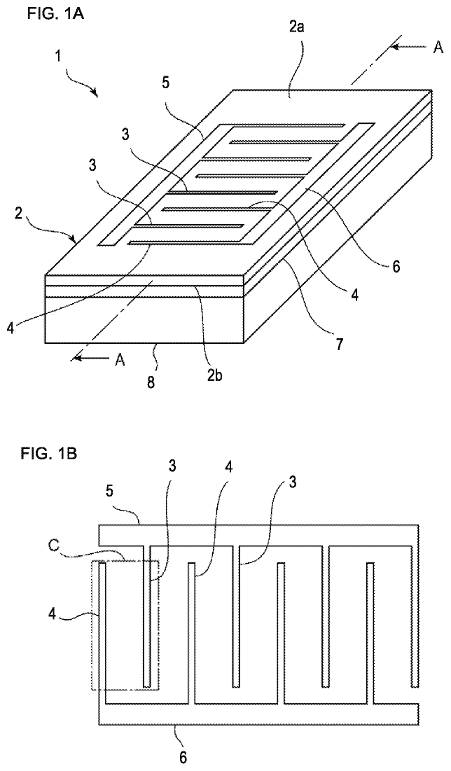

As shown, the acoustic wave device 1 includes a piezoelectric layer 2 made of LiNbO₃. Alternatively, the piezoelectric layer 2 can also be made of LiTaO₃. The cut angle of LiNbO₃ or LiTaO₃ can be Z-cut and can be rotated Y-cut or X-cut. A propagation direction of Y propagation or X propagation of about ±30° can be used, for example. The thickness of the piezoelectric layer 2 is not limited and can be greater than or equal to about 50 nm and can be less than or equal to about 1000 nm, for example, to effectively excite a first thickness-shear mode. The piezoelectric layer 2 has opposed first and second major surfaces 2a, 2b. The electrodes 3, 4 are disposed on the first major surface 2a, but can be disposed on the second major surface 2b in an alternative aspect. For purposes of this disclosure, the electrodes 3 are examples of the “first electrode” and can be referred to as “a plurality of first electrode fingers,” and the electrodes 4 are examples of the “second electrode” and can be referred to as “a plurality of second electrode fingers.” In FIG. 1A and FIGS. 1B, the plurality of electrodes 3 is connected to a first busbar 5, and the plurality of electrodes 4 is connected to a second busbar 6. The electrodes 3, 4 can be interdigitated with each other. The electrodes 3, 4 each can have a rectangular shape and can have a length direction. In a direction perpendicular to the length direction, each of the electrodes 3 and an adjacent one of the electrodes 4 are opposed to each other. In general, an IDT (interdigital transducer) electrode can be defined by the electrodes 3, 4, the first busbar 5, and the second busbar 6. The length direction of the electrodes 3, 4 and the direction perpendicular to the length direction of the electrodes 3, 4 both are directions that intersect with a thickness direction of the piezoelectric layer 2. For this reason, each of the electrodes 3 and the adjacent one of the electrodes 4 can be regarded as being opposed to each other in the direction that intersects with the thickness direction of the piezoelectric layer 2. Alternatively, the length direction of the electrodes 3, 4 can be interchanged with the direction perpendicular to the length direction of the electrodes 3, 4, shown in FIGS. 1A and 1B. In other words, in FIGS. 1A and 1B, the electrodes 3, 4 can extend in a direction in which the first busbar 5 and the second busbar 6 extend. In this case, the first busbar 5 and the second busbar 6 extend in the direction in which the electrodes 3, 4 extend in FIGS. 1A and 1B. Pairs of adjacent electrodes 3 connected to one potential and electrodes 4 connected to the other potential are provided in the direction perpendicular to the length direction of the electrodes 3, 4. A state where the electrodes 3, 4 are adjacent to each other does not mean that the electrodes 3, 4 are in direct contact with each other and instead means that the electrodes 3, 4 are disposed via a gap. When the electrodes 3, 4 are adjacent to each other, no electrode connected to a hot electrode or a ground electrode, including the other electrodes 3, 4, is disposed between the electrodes 3, 4.

It is noted that the number of the pairs of electrodes 3, 4 is not necessarily an integer number of pairs and can be 1.5 pairs, 2.5 pairs, or the like. For example, 1.5 pairs of electrodes means that there are three electrodes 3, 4, two of which is in a pair of electrodes and one of which is not in a pair of electrodes. A distance between the centers of the electrodes 3, 4, that is, the pitch of the electrodes 3, 4, can fall within the range of greater than or equal to about 1 μm and less than or equal to about 10 μm, for example. A distance between the centers of the electrodes 3, 4 can be a distance between the center of the width dimension of the electrodes 3, 4 in the direction perpendicular to the length direction of the electrodes 3, 4. In addition, when there is more than one electrode 3, 4 (e.g., when the number of electrodes 3, 4 is two such that the electrodes 3, 4 define an electrode pair, or when the number of electrodes 3, 4 is three or more such that electrodes 3, 4 define 1.5 or more electrode pairs), a distance between the centers of the electrodes 3, 4 means an average of a distance between any adjacent electrodes 3, 4 of the 1.5 or more electrode pairs. The width of each of the electrodes 3, 4, that is, the dimension of each of the electrodes 3, 4 in the opposed direction that is perpendicular to the length direction, can fall within the range of greater than or equal to about 150 nm and less than or equal to about 1000 nm, for example. Moreover, a distance between the centers of the electrodes 3, 4 can be a distance between the center of the dimension of the electrode 3 in the direction perpendicular to the length direction of the electrode 3 (e.g., the width dimension) and the center of the dimension of the electrode 4 in the direction perpendicular to the length direction of the electrode 4 (e.g., the width dimension).

Because the Z-cut piezoelectric layer in an exemplary aspect, the direction perpendicular to the length direction of the electrodes 3, 4 is a direction perpendicular to a polarization direction of the piezoelectric layer 2. When a piezoelectric body with another cut angle is used as the piezoelectric layer 2, this does not apply. For purposes of this disclosure, the term “perpendicular” is not limited only to a strictly perpendicular case and can be substantially perpendicular (e.g., an angle formed between the direction perpendicular to the length direction of the electrodes 3, 4 and the polarization direction can be, for example, about 90°±10°).

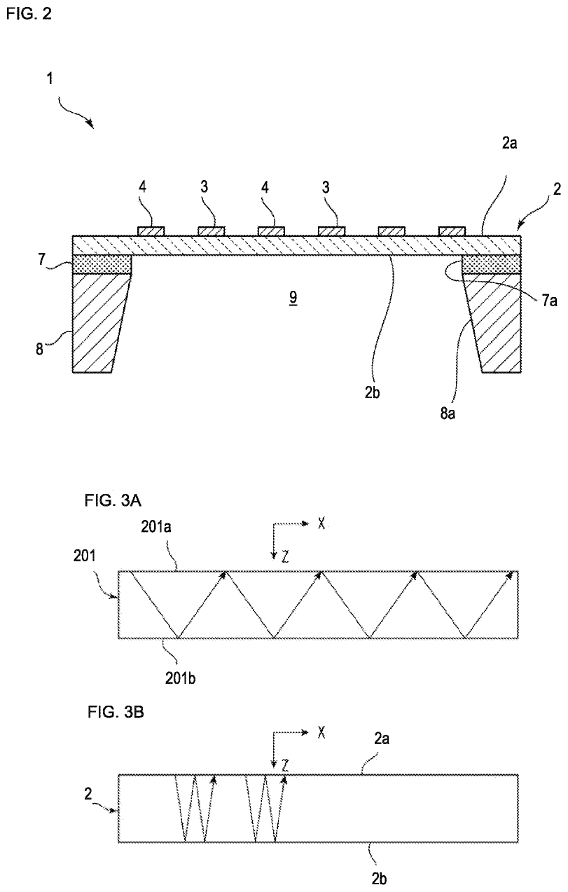

Moreover, a support substrate 8 can be laminated via an electrically insulating layer or an electrically insulating or dielectric film 7 to the second major surface 2b of the piezoelectric layer 2. As shown in FIG. 2, the electrically insulating layer 7 can have a frame shape and can include an opening 7a, and the support substrate 8 can have a frame shape and can include an opening 8a. With this configuration, a cavity 9 can be formed in the electrically insulating layer and/or in the support substrate 8 according to exemplary aspects. The cavity 9 can be provided so as not to impede vibrations of an excitation region C of the piezoelectric layer 2. Therefore, the support substrate 8 can be laminated to the second major surface 2b via the electrically insulating layer 7 at a location that does not overlap a portion where at least one electrode pair is provided. The electrically insulating layer 7 does not need to be provided in an alternative aspect. Therefore, the support substrate 8 can be laminated directly or indirectly on the second major surface 2b of the piezoelectric layer 2.

The electrically insulating layer 7 can be made of silicon oxide. Other than silicon oxide, an appropriate electrically insulating material, such as silicon oxynitride and alumina, can also be used. The support substrate 8 can be made of Si or other suitable material. A plane direction of the Si can be (100) or (110) or (111). High-resistance Si with a resistivity higher than or equal to about 4 kΩ, for example, can be used. The support substrate 8 can also be made of an appropriate electrically insulating material or an appropriate semiconductor material. Examples of the material of the support substrate 8 include a piezoelectric body, such as aluminum oxide, lithium tantalate, lithium niobate, and quartz crystal; various ceramics, such as alumina, magnesia, sapphire, silicon nitride, aluminum nitride, silicon carbide, zirconia, cordierite, mullite, steatite, and forsterite; a dielectric, such as diamond and glass; and a semiconductor, such as gallium nitride.

The first and the second electrodes 3, 4 and the first and the second busbars 5, 6 can be made of an appropriate metal or alloy, such as Al and AlCu alloy. The first and the second electrodes 3, 4 and the first and the second busbars 5, 6 can include a structure such as an Al film that can be laminated on a Ti film. An adhesion layer other than a Ti film can be used in alternative aspects.

In operation, to drive the acoustic wave device 1, an alternating-current voltage is applied between the first and the second electrodes 3, 4. More specifically, an alternating-current voltage is applied between the first and the second busbar 5, 6 to excite a bulk wave in a first thickness-shear mode in the piezoelectric layer 2. In the acoustic wave device 1, when the thickness of the piezoelectric layer 2 is d and a distance between the centers of adjacent first and second electrodes 3, 4 of the electrode pairs is p, the ratio d/p can be less than or equal to about 0.5, for example. For this reason, a bulk wave in the first thickness-shear mode can be effectively excited, which results in good resonant characteristics being obtained. The ratio d/p can be less than or equal to about 0.24, and, in this case, even more improved resonant characteristics can be obtained. When there is more than one electrode, the distance p between the centers of the adjacent electrodes 3, 4 is an average distance of the distance between the centers of any adjacent electrodes 3, 4.

With the above configuration, the Q value or quality factor of the acoustic wave device 1 is unlikely to decrease, even when the number of electrode pairs is reduced for size reduction. That is, the Q value is unlikely to decrease if the number of electrode pairs is reduced because the acoustic wave device 1 is a resonator that needs no reflectors on both sides, and therefore, a propagation loss is small. No reflectors are needed because a bulk wave in a first thickness-shear mode is used.

The difference between a Lamb wave used in conventional acoustic wave devices and a bulk wave in the first thickness-shear mode used in exemplary embodiments of the present invention is described with reference to FIGS. 3A and 3B.

FIG. 3A is a schematic elevational cross-sectional view for illustrating a Lamb wave propagating in a piezoelectric film of an acoustic wave device as described in Japanese Unexamined Patent Application Publication No. 2012-257019.

The wave propagates in a piezoelectric film 201 as indicated by the arrows in FIG. 3A. In the piezoelectric film 201, a first major surface 201a and a second major surface 201b are opposed to each other, and a thickness direction connecting the first major surface 201a and the second major surface 201b is a Z direction. An X direction is a direction in which electrode fingers of an interdigital transducer electrode are arranged. As shown in FIG. 3A, a Lamb wave propagates in the X direction. The Lamb wave is a plate wave, so the piezoelectric film 201 vibrates as a whole. However, the wave propagates in the X direction. Therefore, resonant characteristics are obtained by arranging reflectors on both sides. For this reason, a wave propagation loss occurs, and the Q value or quality factor decreases when the size is reduced, that is, when the number of electrode pairs is reduced.

In contrast, as shown in FIG. 3B, in the acoustic wave device 1, a vibration displacement is caused in the thickness-shear direction, so the wave propagates substantially in the direction connecting the first and the second major surfaces 2a, 2b of the piezoelectric layer 2, that is, the Z direction, and resonates. In other words, the X-direction component of the wave is significantly smaller than the Z-direction component. Since the resonant characteristics are obtained from the propagation of the wave in the Z direction, no reflectors are needed. Thus, there is no propagation loss caused when the wave propagates to reflectors. Therefore, even when the number of electrode pairs is reduced to reduce size, the Q value or quality factor is unlikely to decrease.

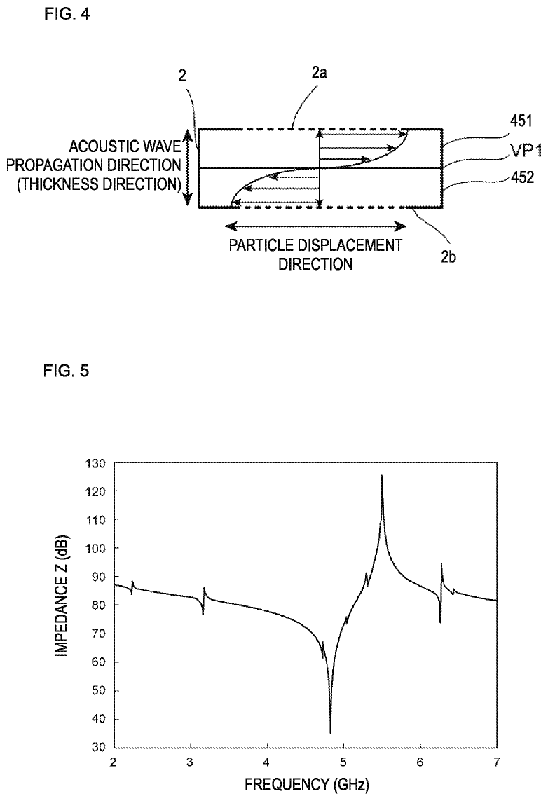

As shown in FIG. 4, the amplitude direction of the bulk wave in the first thickness-shear mode is opposite in a first region 451 included in the excitation region C of the piezoelectric layer 2 and a second region 452 included in the excitation region C, where the excitation region C is shown in FIG. 1B. FIG. 4 schematically shows a bulk wave when a higher voltage is applied to the electrodes 4 than a voltage applied the electrodes 3. The first region 451 is a region in the excitation region C between the first major surface 2a and a virtual plane VP1 that is perpendicular to the thickness direction of the piezoelectric layer 2 and that divides the piezoelectric layer 2 into two. The second region 452 is a region in the excitation region C between the virtual plane VP1 and the second major surface 2b.

As described above, the acoustic wave device 1 includes at least one electrode pair. However, the wave is not propagated in the X direction, so the number of electrode pairs does not necessarily need to be two or more. In other words, only one electrode pair can be provided.

For example, the first electrode 3 is an electrode connected to a hot potential, and the second electrode 4 is an electrode connected to a ground potential. Of course, the first electrode 3 can be connected to a ground potential, and the second electrode 4 can be connected to a hot potential in an alternative aspect. Moreover, each first or second electrode 3, 4 can be connected to a hot potential or can be connected to a ground potential as described above, and no floating electrode is provided.

FIG. 5 is a graph showing the resonant characteristics of the acoustic wave device 1. The design parameters of the acoustic wave device 1 having the resonant characteristics are as follows. The piezoelectric layer 2 is made of LiNbO₃ with Euler angles of (0°, 0°, 90°) and has a thickness of about 400 nm, for example. But, as explained above, the piezoelectric layer 2 can be LiTaO₃, and other suitable Euler angles and thicknesses can be used.

When viewed in a direction perpendicular to the length direction of the first and the second electrodes 3, 4, the length of a region in which the first and the second electrodes 3, 4 overlap, that is, the excitation region C, can be about 40 μm, the number of electrode pairs of electrodes 3, 4 can be 21, the distance between the centers of the first and the second electrodes 3, 4 can be about 3 μm, the width of each of the first and the second electrodes 3, 4 can be about 500 nm, and the ratio d/p can be about 0.133, for example.

The electrically insulating layer 7 can be made of a silicon oxide film having a thickness of about 1 μm, for example.

The support substrate 8 can be made of Si.

The length of the excitation region C can be along the length direction of the first and the second electrodes 3, 4.

The distance between any adjacent electrodes of the electrode pairs can be equal or substantially equal within manufacturing and measurement tolerances among all of the electrode pairs. In other words, the first and the second electrodes 3, 4 can be disposed at a constant pitch.

As is apparent from FIG. 5, although no reflectors are provided, good resonant characteristics with a fractional bandwidth of about 12.5% can be obtained.

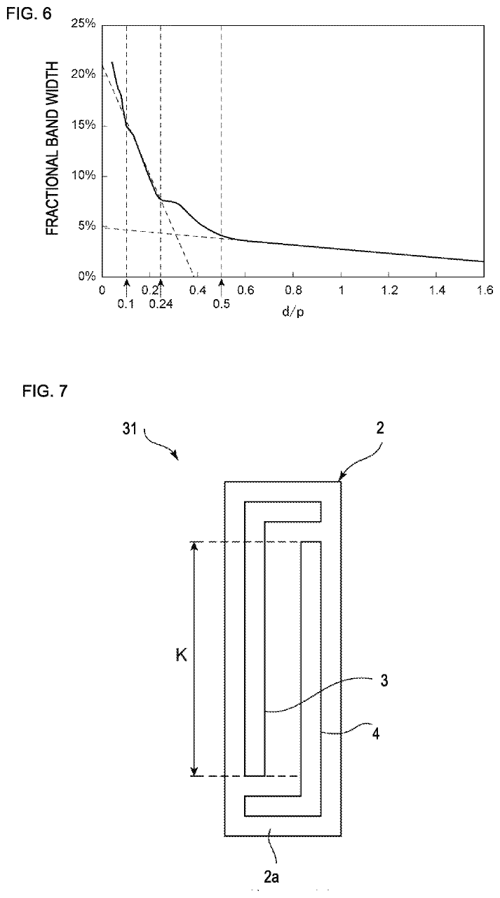

When the thickness of the piezoelectric layer 2 is d and the distance between the centers of the electrode pairs is p, the ratio d/p can be less than or equal to about 0.5 or can be less than or equal to about 0.24, for example. The ratio d/p will be further discussed with reference to FIG. 6 below.

Acoustic wave devices can be provided with different ratios d/p as in the case of the acoustic wave device having the resonant characteristics shown in FIG. 5. FIG. 6 is a graph showing the relationship between the ratio d/p and the fractional bandwidth when the acoustic wave device 1 is used as a resonator.

As is apparent from the non-limiting example shown in FIG. 6, when the ratio d/p>0.5, the fractional bandwidth is lower than about 5%, even when the ratio d/p is adjusted. In contrast, in the case where the ratio d/p≤0.5, the ratio d/p changes within the range, and the fractional bandwidth can be set to about 5% or higher, that is, a resonator having a high coupling coefficient can be provided, for example. In the case where the ratio d/p is lower than or equal to about 0.24, the fractional bandwidth can be increased to about 7% or higher, for example. In addition, when the ratio d/p is adjusted within the range, a resonator having an even wider fractional bandwidth can be obtained, so a resonator having an even higher coupling coefficient can be achieved. Therefore, when the ratio d/p is set to about 0.5 or less, for example, a resonator that uses a bulk wave in the first thickness-shear mode with a high coupling coefficient is provided.

As described above, at least one electrode pair can be one pair, and, in the case of one electrode pair, p is defined as the distance between the centers of the adjacent first and second electrodes 3, 4. In the case of 1.5 or more electrode pairs, an average distance of the distance between the centers of any adjacent electrodes 3, 4 can be defined as p.

For the thickness d of the piezoelectric layer 2, when the piezoelectric layer 2 has thickness variations, an average value of the thicknesses can be used.

FIG. 7 is a plan view of an acoustic wave device 31 according to a second exemplary embodiment. In the acoustic wave device 31, one electrode pair including the first and the second electrodes 3, 4 is provided on the first major surface 2a of the piezoelectric layer 2. Alternatively, the electrodes 3, 4 can be provided on the second major surface 2b of the piezoelectric layer 2. In FIG. 7, K is an overlap width. As described above, in the acoustic wave device 31, the number of electrode pairs can be one. In this case as well, when the ratio d/p is less than or equal to about 0.5, for example, a bulk wave in a first thickness-shear mode can be effectively excited.

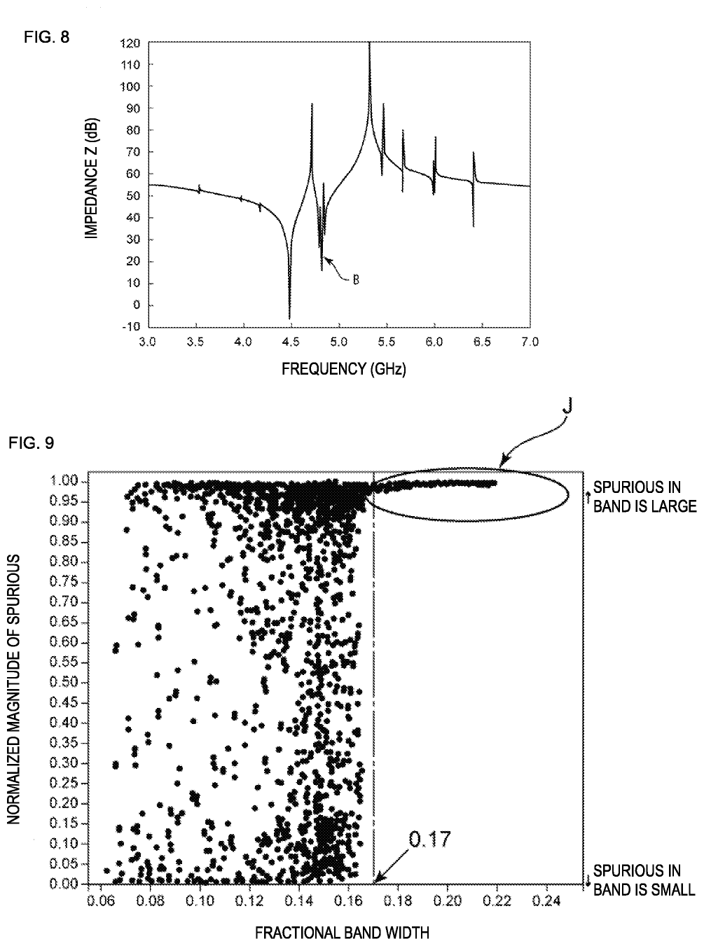

In the acoustic wave device 31, a metallization ratio MR of an area of any adjacent first and second electrodes 3, 4 within the excitation region, i.e., a region in which any adjacent electrodes 3, 4 overlap when viewed in the opposed direction, to a total area of the excitation region C, can satisfy MR≤1.75 (d/p)+0.075, effectively reducing spurious occurrences. This reduction will be described with reference to FIGS. 8 and 9. FIG. 8 is a reference graph showing an example of the resonant characteristics of the acoustic wave device 31. The spurious occurrence indicated by the arrow B appears between a resonant frequency and an anti-resonant frequency. The ratio d/p can be set to about 0.08, and the Euler angles of LiNbO₃ can be set to (0°, 0°, 90°), for example. The metallization ratio MR can be set to about 0.35, for example.

The metallization ratio MR will be described with reference to FIG. 1B. In the electrode structure of FIG. 1B, when focusing on one electrode pair, it is assumed that only the one electrode pair is provided. In this case, the portion surrounded by the alternate long and short dashed line C is the excitation region. The excitation region C includes, when the first and the second electrodes 3, 4 are viewed in the direction perpendicular to the length direction of the first and the second electrodes 3, 4, that is, the opposed direction, a first region of the first electrode 3 overlapping with the second electrode 4, a second region of the second electrode 4 overlapping with the first electrode 3, and a third region in which the first and the second electrodes 3, 4 overlap in a region between the first and the second electrodes 3, 4. Then, the ratio of the areas of the first and the second electrodes 3, 4 in the excitation region C to the area of the excitation region C is the metallization ratio MR. In other words, the metallization ratio MR is the ratio of the area of a metallization portion to the area of the excitation region C.

When a plurality of electrode pairs is provided, the ratio of a metallization portion included in the total excitation region to the total area of the excitation region is the metallization ratio MR. That is, the metallization ratio MR can be the ratio of an areas of the first and the second electrodes 3, 4 within an overlapping region, i.e., a region in which the first and the second electrodes 3, 4 overlap each other, to a total area of the overlapping region.

FIG. 9 is a graph showing the relationship between a fractional bandwidth and a magnitude of normalized spurious for a large number of acoustic wave resonators in which a phase rotation amount of impedance of spurious is normalized by 180° as the magnitude of spurious. The phase rotation amount of impedance is an indicator of the magnitude of spurious, which is related to the impedance ratio. The impedance ratio relates to the difference between the minimum value and the maximum value of the impedance, while the phase rotation amount of impedance relates to the peak value of the impedance. For the fractional bandwidth, the film thickness of the piezoelectric layer 2 and the dimensions of the first and the second electrodes 3, 4 are variously changed and adjusted. FIG. 8 is graph showing the resonant characteristics when material of the piezoelectric layer 2 is Z-cut LiNbO₃, and similar resonant characteristics can be obtained when the material of the piezoelectric layer 2 uses another cut angle.

In a region surrounded by the ellipse J in FIG. 9, the spurious is about 1.0 and large. As is apparent from FIG. 9, when the fractional bandwidth exceeds about 0.17, that is, about 17%, large spurious having a spurious level greater than or equal to one appears in a pass band, even when parameters of the fractional bandwidth are changed. In other words, as in the case of the resonant characteristics shown in FIG. 8, large spurious indicated by the arrow B appears in the pass band. Thus, the fractional bandwidth is preferably lower than or equal to about 17%, for example. In this case, spurious can be reduced by adjusting the film thickness of the piezoelectric layer 2, the dimensions of the first and the second electrodes 3, 4, and the like.

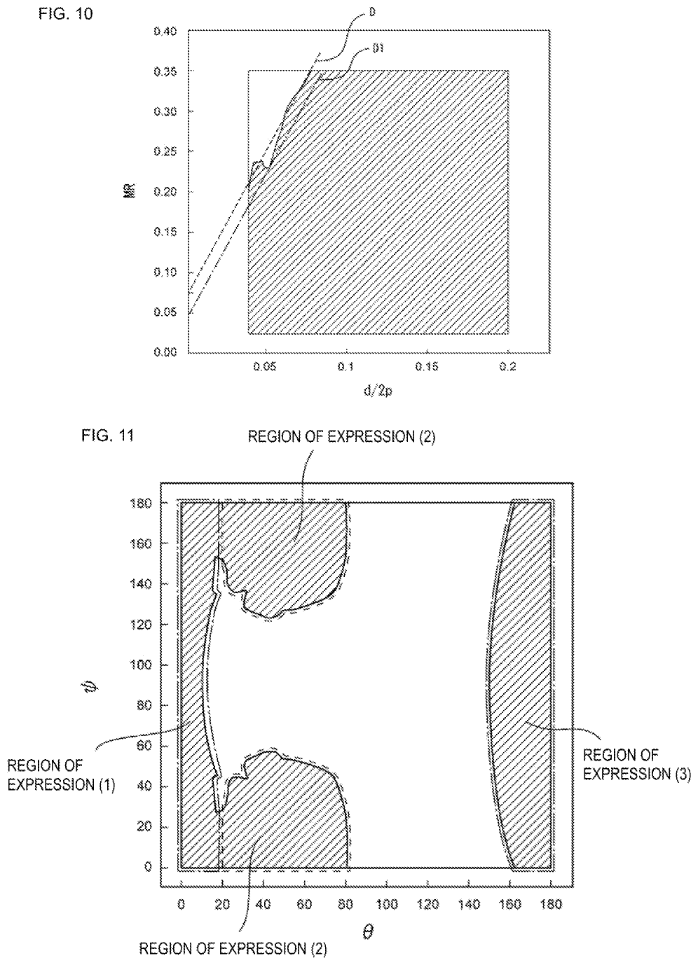

FIG. 10 is a graph showing the relationship among the ratio d/2p, the metallization ratio MR, and the fractional bandwidth. The fractional bandwidths of various acoustic wave devices with different ratios d/2p and with different metallization ratios MR are measured. The hatched portion on the right-hand side of the dashed line D in FIG. 10 is a region in which the fractional bandwidth is lower than or equal to about 17%, for example. The dashed line D between the hatched region and a non-hatched region is expressed by MR=3.5 (d/2p)+0.075=1.75 (d/p)+0.075. When the metallization ratio MR satisfies MR≤1.75 (d/p)+0.075, the fractional bandwidth can be set to about 17% or lower, for example. Additionally, FIG. 10 shows a long- and short-dashed line D1 expressed by MR=3.5 (d/2p)+0.05. When the metallization ratio MR satisfies MR≤1.75 (d/p)+0.05, the fractional bandwidth can be reliably set to about 17% or lower, for example.

FIG. 11 is a diagram showing a map of the fractional bandwidth for the Euler angles (0°, θ, ψ) of LiNbO₃ when the ratio d/p is brought close to zero without limit. The hatched portions in FIG. 11 are regions in which the fractional bandwidth is at least about 5% or higher, and the boundaries of the hatched portions are approximated by the following expressions (1), (2), and (3):

(0°±10°,0° to 20°, any ψ) (1)

(0°±10°,20° to 80°,0° to 60°(1−(θ−50)²/900)^{1/2}) or

(0°±10°,20° to 80°,[180°−60°(1−(θ−50)²/900)^{1/2}] to 180°) (2)

(0°±10°,[180°−30°(1−(ψ−90)²/8100)^{1/2}] to 180°, any ψ) (3)

Therefore, when the Euler anglers of the material used for the piezoelectric layer 2 of an acoustic wave resonator satisfy the above expressions (1), (2), and (3), the fractional bandwidth of the acoustic wave resonator can be sufficiently widened.

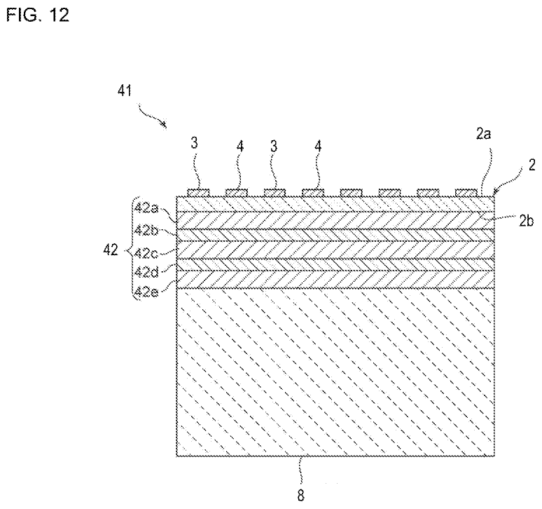

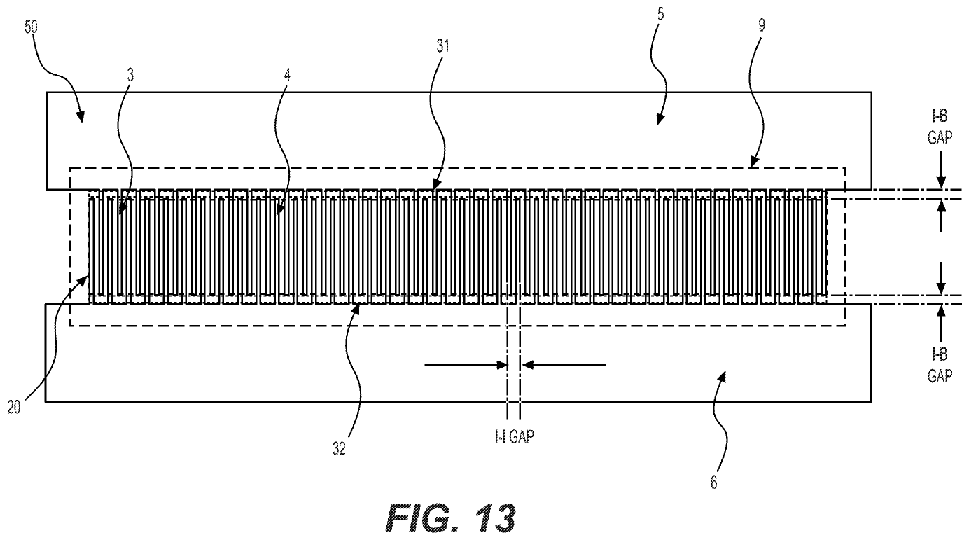

FIG. 12 is a cross-sectional view of an acoustic wave device 41 that includes an acoustic multilayer film 42 laminated on the second major surface 2b of the piezoelectric layer 2. The acoustic multilayer film 42 includes a multilayer structure of low acoustic impedance layers 42a, 42c, 42e having a relatively low acoustic impedance and of high acoustic impedance layers 42b, 42d having a relatively high acoustic impedance. This multilayer structure can be referred to as a Bragg mirror or Bragg reflector. Using the acoustic multilayer film 42 allows a bulk wave in a first thickness-shear mode to be enclosed in the piezoelectric layer 2 without using the cavity 9 in the acoustic wave device 1. In the acoustic wave device 41, resonant characteristics based on a bulk wave in a first thickness-shear mode can be obtained by setting the ratio d/p to about 0.5 or less. In the acoustic multilayer film 42, the number of the laminated low acoustic impedance layers 42a, 42c, 42e and the number of the laminated high acoustic impedance layers 42b, 42d are not limited. The bulk wave in a first thickness-shear mode can be enclosed if at least one of the high acoustic impedance layers 42b, 42d is farther from the piezoelectric layer 2 than the low acoustic impedance layers 42a, 42c, 42e.

The low acoustic impedance layers 42a, 42c, 42e and the high acoustic impedance layers 42b, 42d can include any suitable materials such that the relationship among the acoustic impedance layers is satisfied. Examples of the material of the low acoustic impedance layers 42a, 42c, 42e may include, for example, silicon oxide and silicon oxynitride. Examples of the material of the high acoustic impedance layers 42b, 42d may include, for example, alumina, silicon nitride, and metals.

FIG. 13 illustrates an acoustic wave device 1 that includes a support substrate 8, a piezoelectric layer 2 on the support substrate 8, and an interdigital transducer (IDT) electrode 50 on the piezoelectric layer 2. The IDT electrode includes first and second busbars 5, 6 and first and second electrodes 3, 4. The support substrate 8 can optionally include an electrically insulating layer or dielectric film (not shown in FIG. 7, but similar to the electrically insulating layer 7 in FIGS. 1A and 2). The electrically insulating layer can be on the support substrate 8, and the piezoelectric layer 2 can be on the electrically insulating layer, if included. The support substrate 8 includes a cavity 9, an outline of which is shown as a rectangle in FIG. 13, that opens in a direction toward the piezoelectric layer 2. If an electrically insulating layer is used, then the cavity 9 can be provided only in the electrically insulating layer or can be provided in both the support substrate 8 and the electrically insulating layer. At least a portion of the IDT electrode 50 overlaps the cavity 9 when viewed in a direction in which the support substrate 8 and the piezoelectric layer 2 are stacked. The electrically insulating layer can include SiO₂, for example. In an alternative aspect, the electrically insulating layer 7 may not be included in the acoustic wave device 1. Moreover, the first and second electrodes 3, 4 can be disposed on either the front or back surface of the piezoelectric layer 2 according to various exemplary aspects.

As further shown, the IDT electrode 50 includes first and second busbars 5, 6 that face each other, multiple first electrodes 3 defining first fingers that each include a base end that is connected to the first busbar 5 and that each extends toward the second busbar 6, and multiple second electrodes 4 defining second fingers that each include a base end that is connected to the second busbar 6 and that each extends toward the first busbar 5. The first electrodes 3 and the second electrodes 4 can be interdigitated with each other. The IDT electrode 50 has an intersection region 20, a first gap region 31, and a second gap region 32. The intersection region 20 is a region in which adjacent first electrodes 3 and second electrodes 4 overlap with each other when viewed in a direction in which the first electrodes 3 and the second electrodes 4 face each other. The first gap region 31 is a region between the intersection region 20 and the first busbar 5. The second gap region 32 is a region between the intersection region 20 and the second busbar 6.

Dimensions of the first gap region 31 and the second gap region 31 in a direction in which the first electrodes 3 and the second electrodes 4 extend are referred to as IDT-busbar gaps or I-B gaps. As for the IDT electrode 50 of the exemplary aspect, the I-B gap of the first gap region 31 is less than or equal to about 1.1p, within manufacturing and measurement tolerances, where p (the “pitch”) is a distance between the centers (i.e., the center-to-center spacing) of adjacent first and second electrodes 3, 4. The I-B gap of the second gap region 32 can also be less than or equal to about 1.1p, within manufacturing and measurement tolerances. The IDT-IDT gap or I-I gap is the distance between facing edges of the adjacent first and second electrodes 3, 4, which is smaller than the distance p between the centers of the adjacent first and second electrodes 3, 4.

For example, the I-B gaps are preferably greater than or equal to about 0.5 μm, within manufacturing and measurement tolerances, because, when the I-B gaps are less than about 0.5 μm, manufacturing the IDT electrode 50 can be difficult.

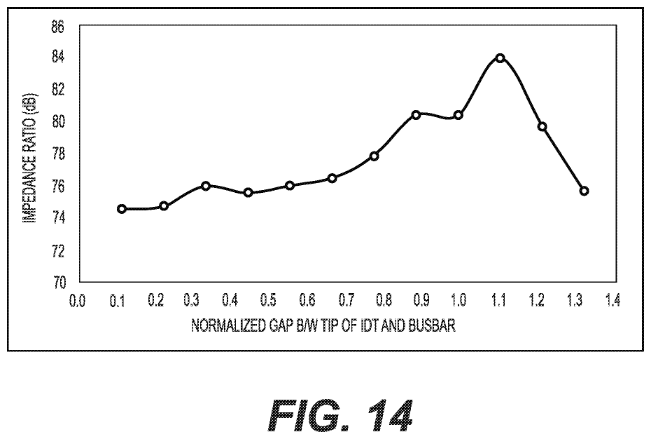

FIG. 14 shows a plot of the impedance ratio of a one-port resonator when the I-B gaps are changed in the acoustic wave device 1. The x-axis values are values obtained by normalizing the values of the I-B gaps by using the distance p (e.g., about 4.55 μm) between the centers of the adjacent electrode fingers. As illustrated in FIG. 14, when the values of the I-B gaps are about 1.1p (e.g., about 5 μm), the impedance ratio is the maximum (about 85 dB). When the values of the I-B gaps are greater than about 1.1p, the impedance ratio greatly decreases. Accordingly, when the I-B gaps are less than or equal to about 1.1p, an acoustic wave device that has good resonant characteristics can be obtained.

The parameters of an example of the one-port resonator used to generate FIG. 14 include:
Piezoelectric Layer: ZYLN (Thickness: 500 nm)
IDT electrode: Al (Thickness: 500 nm)
Two-layer Wiring Line: Al (Thickness: 3 μm)
Joining Layer: SiO₂ (Thickness: 600 nm)
Support Substrate: Si (250 μm)
Distance between Centers of Electrode Fingers p: 4.55 μm
Total Number of Electrode Fingers: 80
Line Width of Electrode Fingers: 1.1 μm
I-I Gap: 3.45 μm
Overlap Width: 50 μm
Applied Alternating Voltage (Pin): about 200 mW
   where a two-layer wiring line is a wiring line that is stacked on a busbar of the IDT electrode and that is connected to, for example, another element or an electrode pad.

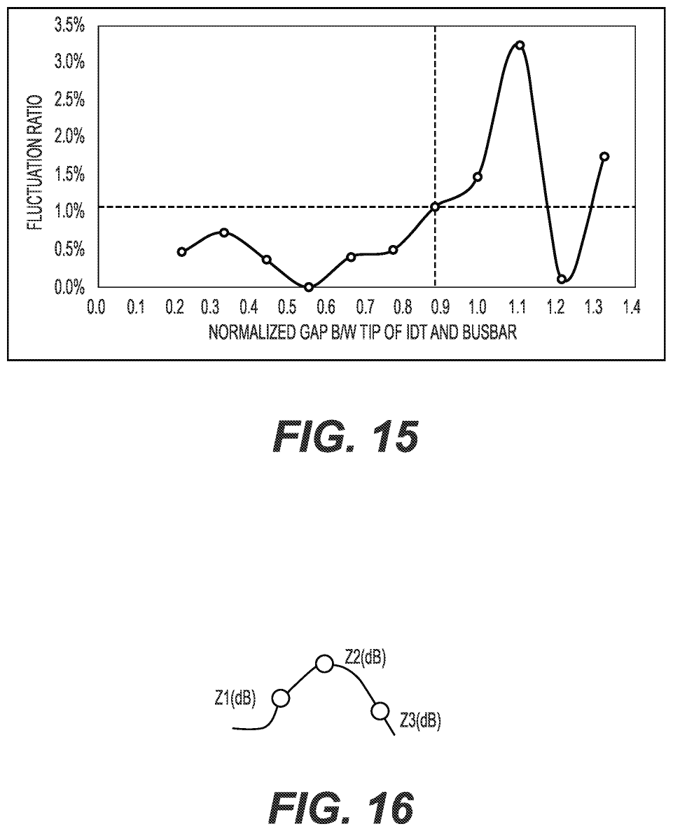

FIG. 15 shows variation in the value of a fluctuation ratio of the impedance ratio at a Z2 point when the I-B gaps are changed, where the fluctuation ratio is based on equation (4):

$$= \frac{\vert Z2 - \frac{( {Z}_{1} + {Z}_{2} + {Z}_{3} )}{3} \vert}{\frac{( {Z}_{1} + {Z}_{2} + {Z}_{3} )}{3}} \qquad ( 4 )$$

Where the denominator is the average of the impedance ratios including those before and after, and the numerator is the deviation (e.g., the amount of fluctuation) from the average. FIG. 16 shows a possible plot of impedances ratios Z1, Z2, Z3 used to calculate the fluctuation ratio. FIG. 15 shows that, when the I-B gaps are maintained to be less than or equal to about 0.9p, the amount of fluctuation of the impedance ratio is decreased to an amount of about 1% or less and that a yield of the acoustic wave devices can be improved. Thus, acoustic wave devices that has good resonant characteristics can be reliably obtained. Accordingly, the I-B gaps are preferably less than or equal to about 0.9p.

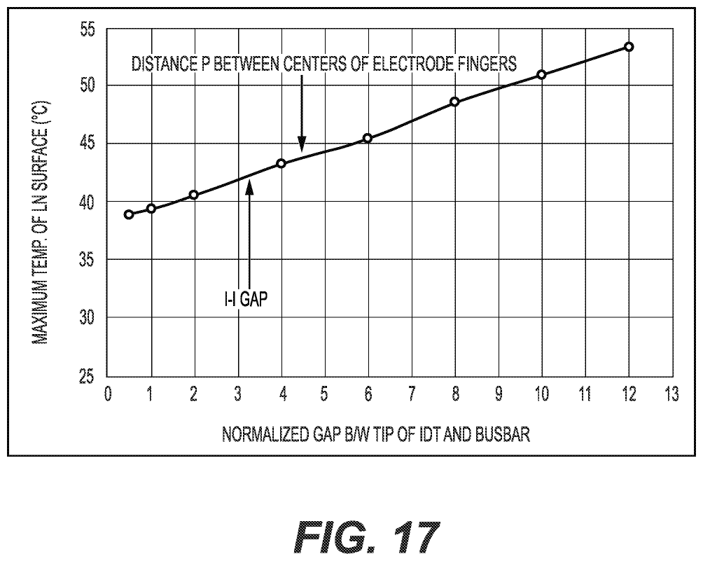

FIG. 17 shows the variation in the maximum temperature of a surface of the piezoelectric layer 2 when the I-B gaps are changed in the acoustic wave device 1. As shown in FIG. 17, as the values of the I-B gaps decrease, the maximum temperature of the surface of the piezoelectric layer 2 decreases, and that the heat dissipation of the acoustic wave devices 1 is improved. For example, when the values of the I-B gaps are less than the distance p between the centers of the adjacent electrode fingers, the maximum temperature is less than about 45° C. For example, when the values of the I-B gaps are less than the distance (I-I gap) between the adjacent electrode fingers, the maximum temperature further decreases.

In general, it is noted that each of the exemplary embodiments described herein is illustrative and that partial substitutions or combinations of configurations are possible among different embodiments as would be appreciated to one skilled in the art. While exemplary embodiments of the present invention have been described above, it is to be understood that variations and modifications will be apparent to those skilled in the art without departing from the scope and spirit of the present invention.

What is claimed:

1. An acoustic wave device comprising:
a support substrate;
a piezoelectric layer on the support substrate and including lithium tantalate or lithium niobate; and
an interdigital transducer electrode on the piezoelectric layer and including two busbars and a plurality of electrode fingers extending from the two busbars,
wherein a ratio d/p is less than or equal to 0.5, where d is a thickness of the piezoelectric layer and p is a distance between centers of adjacent electrode fingers of the plurality of electrode fingers, and
wherein the interdigital transducer electrode further includes:
an intersection region in which the adjacent electrode fingers overlap when viewed in a direction in which the plurality of electrode fingers face each other, and
two gap regions between the intersection region and respective busbars of the two busbars that each form an I-B gap in a direction in which the plurality of electrode fingers extend,
wherein the I-B gap of at least one of the two gap regions is less than or equal to 1.1p.

2. The acoustic wave device according to claim 1, wherein the I-B gap of both of the two gap regions is less than or equal to 1.1p.

3. The acoustic wave device according to claim 1, wherein the I-B gap of at least one of the two gap regions is greater than or equal to 0.5 μm and less than or equal to 1.1p.

4. The acoustic wave device according to claim 1, wherein the I-B gap of at least one of the two gap regions is less than or equal to 0.9p.

5. The acoustic wave device according to claim 1, wherein the support substrate includes an electrically insulating layer adjacent to the piezoelectric layer.

6. The acoustic wave device according to claim 5, wherein the electrically insulating layer includes a cavity that faces the piezoelectric layer, and at least a portion of the intersection region overlaps the cavity in a plan view of the electrically insulating layer.

7. The acoustic wave device according to claim 1, wherein the support substrate includes a cavity that faces the piezoelectric layer, and at least a portion of the intersection region overlaps the cavity in a plan view of the support substrate.

8. The acoustic wave device according to claim 1, wherein the ratio d/p is less than or equal to 0.24.

9. The acoustic wave device according to claim 1, wherein MR≤1.75 (d/p)+0.075, where MR is a metallization ratio of an area of the plurality of electrode fingers to a total area of the intersection region of the interdigital transducer electrode.

10. An acoustic wave device comprising:
a support substrate including a cavity;
a piezoelectric layer supported by the support substrate; and
an interdigital transducer electrode on the piezoelectric layer at least partially overlapping the cavity in a plan view of the support substrate and including:
a first bus bar;
first electrode fingers extending from the first bus bar;
a second bus bar;
second electrode fingers extending from the second bar such that the first and the second electrode fingers are interdigitated;
an intersection region in which adjacent first and second electrode fingers overlap when viewed in a direction in which the first and the second electrode fingers face each other;
a first gap region between the intersection region and the first busbar that forms a first I-B gap in a direction in which the first and the second electrode fingers extend; and
a second gap region between the intersection region and the second busbar that forms a second I-B gap in the direction in which the first and the second electrode fingers extend,
wherein a ratio d/p is less than or equal to 0.5, where d is a thickness of the piezoelectric layer and p is a distance between centers of adjacent electrode fingers of the first and second electrode fingers, and
at least one of the first and the second I-B gaps is less than or equal to 1.1p.

11. The acoustic wave device according to claim 10, wherein the first and the second I-B gaps are less than or equal to 1.1p.

12. The acoustic wave device according to claim 10, wherein at least one of the first and the second I-B gaps is greater than or equal to 0.5 μm and less than or equal to 1.1p.

13. The acoustic wave device according to claim 10, wherein at least one of the first and the second I-B gaps is less than or equal to 0.9p.

14. The acoustic wave device according to claim 10, wherein the support substrate includes an electrically insulating layer adjacent to the piezoelectric layer.

15. The acoustic wave device according to claim 14, wherein the cavity extends in the electrically insulating layer and faces the piezoelectric layer, and at least a portion of the intersection region overlaps the cavity in a plan view of the electrically insulating layer.

16. The acoustic wave device according to claim 15, wherein the cavity extends only in the electrically insulating layer.

17. The acoustic wave device according to claim 10, wherein at least a portion of the intersection region overlaps the cavity in a plan view of the support substrate.

18. The acoustic wave device according to claim 10, wherein the ratio d/p is less than or equal to 0.24.

19. The acoustic wave device according to claim 10, wherein MR≤1.75 (d/p)+0.075, where MR is a metallization ratio of an area of the first and second electrode fingers to a total area of the intersection region of the interdigital transducer electrode.

20. The acoustic wave device according to claim 10, wherein the piezoelectric layer includes lithium tantalate or lithium niobate.
